(19) United States
(12) Patent Application Publication
(10) Pub. No.: US 2010/0212731 A1
(43) Pub. Date: Aug. 26, 2010

(54) Photovoltaic Devices Including Controlled Copper Uptake

(75) Inventor: Anke Abken, Whitehouse, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/708,282

(22) Filed: Feb. 18, 2010

Related U.S. Application Data
(60) Provisional application No. 61/155,311, filed on Feb. 25, 2009.

(51) Int. Cl. H01L 31/00; H01L 31/18

(52) U.S. Cl. 136/255; 438/57; 257/E31.001

(57) ABSTRACT

A photovoltaic cell can include a substrate having a copper-doped semiconductor layer. The doping can be mediated with a salt.

### CLAIM FOR PRIORITY

This application claims priority under 35 U.S.C. §119(e) to Provisional U.S. Patent Application Ser. No. 61/155,311 filed on Feb. 25, 2009, which is hereby incorporated by reference.

### TECHNICAL FIELD

This invention relates to photovoltaic devices and controlling copper uptake.

### BACKGROUND

During the fabrication of photovoltaic devices, layers of semiconductor material can be applied to a substrate with one layer serving as a window layer and a second layer serving as the absorber layer. The window layer can allow the penetration of solar radiation to the absorber layer, where the optical power is converted into electrical power. Past photovoltaic devices have been inefficient.

### DESCRIPTION OF DRAWINGS

FIG. 1 is a schematic depicting a method of doping a photovoltaic device using copper chloride.

FIG. 2 is a schematic of a photovoltaic device having multiple layers.

### DETAILED DESCRIPTION

Photovoltaic devices can include multiple layers formed on a substrate (or superstrate). For example, a photovoltaic device can include a barrier layer, a transparent conductive oxide (TCO) layer, a buffer layer, a semiconductor window layer, and a semiconductor absorber layer, formed in a stack on a substrate. Each layer may in turn include more than one layer or film. For example, the semiconductor window layer and semiconductor absorber layer together can be considered a semiconductor layer. The semiconductor layer can include a first film created (for example, formed or deposited) on the TCO layer and a second film created on the first film. Additionally, each layer can cover all or a portion of the device and/or all or a portion of the layer or substrate underlying the layer. For example, a “layer” can mean any amount of any material that contacts all or a portion of a surface.

Copper doping in photovoltaic cells can increase efficiency of the photovoltaic cell. For example, a photovoltaic cell may include one or more semiconductor layers doped with a copper chloride. Excessive copper may result in decreased efficiency. Therefore it may be desirable to mediate the copper uptake though use of a salt, such as, NH₄Cl or NH₄OH.

In general, a method of manufacturing a photovoltaic cell can include depositing a semiconductor layer and doping the layer with a mixture of copper chloride and a nitrogen-containing chloride. The mixture can be a solution. The doped semiconductor layer can have a copper content of up to and including 2 parts per million.

With the copper content produced using the copper chloride and nitrogen-containing chloride mixture, the open circuit voltage of the photovoltaic cell can be increased from the open circuit voltage with the copper content produced using only the copper chloride in solution. With the copper content produced using the copper chloride and nitrogen-containing chloride mixture, the open circuit resistance of the photovoltaic cell can be decreased from the open circuit resistance with the copper content produced using only the copper chloride in solution. With the copper content produced using the copper chloride and nitrogen-containing chloride mixture, the fill factor of the photovoltaic cell can be increased from the fill factor with the copper content produced using only the copper chloride in solution.

A photovoltaic cell can include a substrate and a copper-doped semiconductor layer on the substrate. The copper-doped semiconductor layer can be doped with a mixture of copper chloride and nitrogen-containing chloride. The copper-doped semiconductor layer can have a copper content of up to and including 2 parts per million.

With the copper content produced using the copper chloride and nitrogen-containing chloride mixture, the open circuit voltage of the photovoltaic cell can be increased from the open circuit voltage with the copper content produced using only the copper chloride mixture. With the copper content produced using the copper chloride and nitrogen-containing chloride mixture, the open circuit resistance of the photovoltaic cell can be decreased from the open circuit resistance with the copper content produced using only the copper chloride in solution. With the copper content produced using the copper chloride and nitrogen-containing chloride mixture, the fill factor of the photovoltaic cell can be increased from the fill factor with the copper content produced using only the copper chloride in solution.

A photovoltaic cell can include a substrate and a copper-doped semiconductor layer on the substrate. The copper-doped semiconductor layer can be doped with a mixture of copper chloride and nitrogen-containing hydroxide. The copper-doped back contact can have a copper content of up to and including 2 parts per million.

With the copper content produced using the copper chloride and nitrogen-containing hydroxide mixture, the open circuit voltage of the photovoltaic cell can be increased from the open circuit voltage with the copper content produced using only the copper chloride in solution. With the copper content produced using the copper chloride and nitrogen-containing hydroxide mixture, the open circuit resistance of the photovoltaic cell can be decreased from the open circuit resistance with the copper content produced using only the copper chloride in solution. With the copper content produced using the copper chloride and nitrogen-containing hydroxide mixture, the fill factor of the photovoltaic cell can be increased from the fill factor with the copper content produced using only the copper chloride in solution.

In certain embodiments, the nitrogen-containing chloride or nitrogen-containing hydroxide can be a salt such as an ammonium salt, including an alkyl ammonium, dialkyl ammonium, trialkylammonium, quaternary alkyl ammonium, pyridinium or imidizolium salts of chloride or hydroxide, or mixtures thereof.

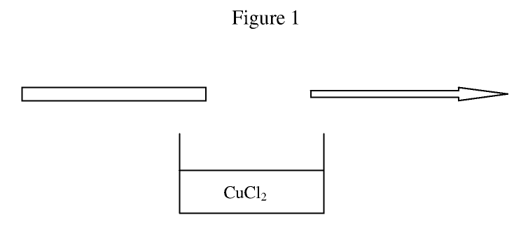

Copper doping in photovoltaic cells can increase efficiency of the photovoltaic in some circumstances and decrease the efficiency if excessive copper is used. Referring to FIG. 1, a method of doping a photovoltaic cell with copper is shown. As shown, a layer of the photovoltaic cell is doped with a copper in solution. Doping may be by surface treating such as vapor or solution, or may be by mechanical milling or made during growth. Copper in the form of CuCl₂ may be added to the layer. A salt such as NH₄Cl or NH₄OH may be added to the CuCl₂ to mediate the CuCl₂ uptake in the deposited layer. A concentration ratio of CuCl₂/NH₄Cl may be between 0.5-2.0. Other salts such as CdCl₂, ZnCl₂, SbCl₃, NaCl, KCl, RbCl, MgCl₂, BeCl₂, SrCl₂, BaCl₂, CaCl₂, AsCl₃, or BiCl₃ may also be used. The layer doped with CuCl₂ has, for example, about 3 ppm of copper. The concentration of copper in bulk using a solution of CuCl₂ with the addition of NH₄Cl is reduced. The concentration of copper decreases with the addition of NH₄Cl to the CuCl₂.

With the addition of NH₄Cl to the CuCl₂, open circuit voltage and open circuit resistance of the photovoltaic cell can be affected. With the reduction of copper uptake using the CuCl₂ and NH₄Cl solution to, for example, less than 2 ppm, V_{oc} (open circuit voltage) is increased and R_{oc} (open circuit resistance) is decreased compared to V_{oc} and R_{oc} of the photovoltaic cell with over 3 ppm of copper. Also, reducing the uptake of copper using the CuCl₂ and NH₄Cl solution increases fill factor.

Experimental data has shown the results of reducing the uptake of copper using the CuCl₂ and NH₄Cl solution. The copper uptake using the CuCl₂ and NH₄Cl solution is reduced by almost 10%. With a greater concentration of NH₄Cl in the solution, the copper uptake can be further reduced by up to 40%. As described above, with the reduction of copper uptake using the CuCl₂ and NH₄Cl solution to less than 2 ppm, V_{oc} is increased compared to V_{oc} of the photovoltaic cell with over 3 ppm of copper. Experimental data has shown an increase of a few percent V_{oc} with the reduction of copper uptake. With a greater concentration of NH₄Cl in the solution, V_{oc} increases by a few percent. With the reduction of copper uptake using the CuCl₂ and NH₄Cl solution to less than 2 ppm, R_{oc} is decreased compared to R_{oc} of the photovoltaic cell with over 3 ppm of copper. Experimental data has shown a decrease of almost 5% R_{oc} with the reduction of copper uptake. With a greater concentration of NH₄Cl in the solution, R_{oc} decreases by 8%. The fill factor is increased in the photovoltaic cell with less than 2 ppm of copper. Experimental data has shown an increase of about 1% fill factor with the reduction of copper uptake. With a greater concentration of NH₄Cl in the solution, the fill factor increases by 2%.

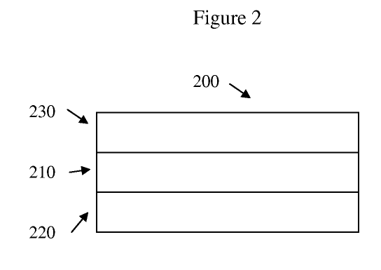

Referring to FIG. 2, a photovoltaic cell 200 can include a semiconductor layer 210. The semiconductor layer 210 can be a CdS/CdTe layer, for example. The semiconductor layer 210 can be deposited on a substrate 220. The substrate 220 can be glass, for example. The photovoltaic cell 200 can include a back metal contact 230. In the CdS/CdTe layer, the CdS layer can be doped with copper.

A common photovoltaic cell can have multiple layers. The multiple layers can include a bottom layer that is a transparent conductive layer, a capping layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. A top substrate layer can be placed on top of the top layer to form a sandwich and complete the photovoltaic cell.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic cells can include a conveyor, for example a roll conveyor with rollers. Other types of conveyors are possible. The conveyor transports substrate into a series of one or more deposition stations for depositing layers of material on the exposed surface of the substrate. Conveyors are described in provisional U.S. application Ser. No. 11/692,667, which is hereby incorporated by reference.

The deposition chamber can be heated to reach a processing temperature of not less than about 450° C. and not more than about 700° C., for example the temperature can range from 450-550° C., 550-650° C., 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations with its own vapor distributor and supply. The distributor can be in the form of a spray nozzle with varying nozzle geometries to facilitate uniform distribution of the vapor supply.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AN, AlP, AlAs, AlSb, GaN, GaP, GaAs, GaSb, InN, InP, InAs, InSb, TlN, TlP, TlAs, TlSb, or mixtures thereof. An example of a window layer and absorbing layer is a layer of CdS coated by a layer of CdTe. A top layer can cover the semiconductor layers. The top layer can include a metal such as, for example, aluminum, molybdenum, chromium, cobalt, nickel, titanium, tungsten, or alloys thereof. The top layer can also include metal oxides or metal nitrides or alloys thereof.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The bottom layer can be a transparent conductive layer, and can be, for example, a transparent conductive oxide such as cadmium stannate oxide, tin oxide, or tin oxide doped with fluorine. Deposition of a semiconductor layer at high temperature directly on the transparent conductive oxide layer can result in reactions that negatively impact of the performance and stability of the photovoltaic device. Deposition of a capping layer of material with a high chemical stability (such as silicon dioxide, dialuminum trioxide, titanium dioxide, diboron trioxide and other similar entities) can significantly reduce the impact of these reactions on device performance and stability. The thickness of the capping layer should be minimized because of the high resistivity of the material used. Otherwise a resistive block counter to the desired current flow may occur. A capping layer can reduce the surface roughness of the transparent conductive oxide layer by filling in irregularities in the surface, which can aid in deposition of the window layer and can allow the window layer to have a thinner cross-section. The reduced surface roughness can help improve the uniformity of the window layer. Other advantages of including the capping layer in photovoltaic cells can include improving optical clarity, improving consistency in band gap, providing better field strength at the junction and providing better device efficiency as measured by open circuit voltage loss. Capping layers are described, for example, in U.S. Patent Publication 20050257824, which is incorporated by reference in its entirety.

The transparent conductive layer can be a transparent conductive oxide, such as a metallic oxide like tin oxide, which can be doped with, for example, fluorine. This layer can be deposited between the front contact and the first semiconductor layer, and can have a resistivity sufficiently high to reduce the effects of pinholes in the first semiconductor layer. Pinholes in the first semiconductor layer can result in shunt formation between the second semiconductor layer and the first contact resulting in a drain on the local field surrounding the pinhole. A small increase in the resistance of this pathway can dramatically reduce the area affected by the shunt.

The bottom layer of a photovoltaic cell can be a transparent conductive layer. A thin capping layer can be on top of and at least covering the transparent conductive layer in part. The next layer deposited is the first semiconductor layer, which can serve as a window layer and can be thinner based on the use of a transparent conductive layer and the capping layer. The next layer deposited is the second semiconductor layer, which serves as the absorber layer. Other layers, such as layers including dopants, can be deposited or otherwise placed on the substrate throughout the manufacturing process as needed.

The transparent conductive layer can be a transparent conductive oxide, such as a metallic oxide like cadmium stannate oxide. This layer can be deposited between the front contact and the first semiconductor layer, and can have a resistivity sufficiently high to reduce the effects of pinholes in the first semiconductor layer.

The first semiconductor layer can serve as a window layer for the second semiconductor layer. The first semiconductor layer can be thinner than the second semiconductor layer. By being thinner, the first semiconductor layer can allow greater penetration of the shorter wavelengths of the incident light to the second semiconductor layer.

The first semiconductor layer can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AN, AlP, AlAs, AlSb, GaN, GaP, GaAs, GaSb, InN, InP, InAs, InSb, TlN, TlP, TlAs, TlSb, or mixtures or alloys thereof. It can be a binary semiconductor, for example it can be CdS. The second semiconductor layer can be deposited onto the first semiconductor layer. The second semiconductor can serve as an absorber layer for the incident light when the first semiconductor layer is serving as a window layer. Similar to the first semiconductor layer, the second semiconductor layer can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, MnO, MnS, MnTe, AN, AlP, AlAs, AlSb, GaN, GaP, GaAs, GaSb, InN, InP, InAs, InSb, TlN, TlP, TlAs, TlSb, or mixtures thereof.

The second semiconductor layer can be deposited onto a first semiconductor layer. A capping layer can serve to isolate a transparent conductive layer electrically and chemically from the first semiconductor layer preventing reactions that occur at high temperature that can negatively impact performance and stability. The transparent conductive layer can be deposited over a substrate.

A number of embodiments have been described. Nevertheless, it will be understood that various modifications may be made without departing from the spirit and scope of the invention. For example, the semiconductor layers can include a variety of other materials, as can the materials used for the buffer layer and the capping layer. In addition, the device may contain interfacial layers between a second semiconductor layer and a back metal electrode to reduce resistive losses and recombination losses at the interface between the second semiconductor and the back metal electrode. Accordingly, other embodiments are within the scope of the following claims.

What is claimed is:

1. A method of manufacturing a photovoltaic device comprising:
depositing a semiconductor layer; and
doping the layer with a mixture of copper chloride and a nitrogen-containing chloride.

2. The method of claim 1, wherein the semiconductor layer has up to and including 2 parts per million of copper.

3. The method of claim 1, whereby the open circuit voltage is increased.

4. The method of claim 1, whereby the open circuit resistance is decreased.

5. The method of claim 1, whereby the fill factor is increased.

6. The method of claim 1, wherein the nitrogen-containing chloride includes ammonium chloride.

7. A photovoltaic cell comprising:
a substrate; and
a copper-doped semiconductor layer on the substrate;
wherein the copper-doped semiconductor layer is doped with a mixture of copper chloride and a nitrogen-containing chloride.

8. The photovoltaic cell of claim 7, wherein the copper-doped semiconductor layer has up to and including 2 parts per million of copper.

9. The photovoltaic cell of claim 7, whereby the open circuit voltage is increased.

10. The photovoltaic cell of claim 7, whereby the open circuit resistance is decreased.

11. The photovoltaic cell of claim 7, whereby the fill factor is increased.

12. The photovoltaic cell of claim 7, wherein the nitrogen-containing chloride includes ammonium chloride.

13. A photovoltaic cell comprising:
a substrate;
a copper-doped semiconductor layer on the substrate;
wherein the copper-doped semiconductor layer is doped with a mixture of copper chloride and a nitrogen-containing hydroxide.

14. The photovoltaic cell of claim 13, wherein the copper-doped semiconductor layer has up to and including 2 parts per million of copper.

15. The photovoltaic cell of claim 13, whereby the open circuit voltage is increased.

16. The photovoltaic cell of claim 13, whereby the open circuit resistance is decreased.

17. The photovoltaic cell of claim 13, whereby the fill factor is increased.

18. The photovoltaic cell of claim 13, wherein the nitrogen-containing hydroxide includes ammonium hydroxide.
